(19) United States
(12) Patent Application Publication
(10) Pub. No.: US 2005/0067627 A1
(43) Pub. Date: Mar. 31, 2005

(54) High efficiency multi-active layer tunnel regenerated white light emitting diode

(76) Inventors: Guangdi Shen, Beijing (CN); Xia Guo, Beijing (CN); Weiling Guo, Beijing (CN); Guo Gao, Beijing (CN)

Correspondence Address: BRUZGA & ASSOCIATES, 11 BROADWAY, STE 400, NEW YORK, NY, 10004, US

(21) Appl. No.: 10/932,429

(22) Filed: Sep. 2, 2004

(30) Foreign Application Priority Data
Sep. 17, 2003 (CN) 03157152.2

(51) Int. Cl. H01L 29/08

(52) U.S. Cl. 257/89

(57) ABSTRACT

A high efficiency and high brightness multi-active layer tunneling regenerated white color semiconductor light emitting diode having a p type electrode 1, a monolithic red light cell 14, a tunnel junction 9, a monolithic green light 15 and blue light cell 16 (or a monolithic cyan light cell 19), wherein each of said cells are electrically connected by tunnel junctions 9, and the red cell physically connected with blue and green cell (or cyan cell) by wafer bonding layer 8. The lights from each cell synthesize white color light. The white light emitting diode only has one time optical-electrical conversion, so the quantum efficiency is high. Moreover, the white LED totally made from semiconductor materials, the lifetime of the white LED lamp is not limited by the relatively short lifetime of fluorescent material.

### FIELD OF THE INVENTION

The present invention relates to the structure of a high efficiency multi-active layer tunnel regenerated white light emitting diode and the method of manufacturing the same, which belong to the field of optoelectronics.

### BACKGROUND OF THE INVENTION

The design structure and problem of conventional white LED:

1. one kind of conventional white LED normally based on the mixing of red, green and blue pure monochromatic light LED which named pixel white LED shown as FIG. 3, 4 and 5. However, it has long been a disadvantage of above white light-emitting diodes: for the pixel white LED, not all colors of visible light were available with the same luminous intensity. The efficiency of light-emitting diodes decreases as the wavelength decreases, that is from red, via green, to blue. The brightness of red and green light-emitting diodes was very good. And such a white light-emitting device is costly. Further, the design of the drive system is very complex because at least four electrical terminals are needed to change currents respectively flowing through different colors of LEDs, so that the intensity of each LED can be adjusted to produce white light. If one of the LEDs suffers from light-output degradation, the color balance of the white light-emitting device is broken.

2. The other kind of conventional white LED is based on a GaN light-emitting diode and a phosphor layer shown as FIG. 6. The white LED lamp includes a blue LED chip and fluorescent material. The white LED lamp produces white light by compounding blue light emitted by the LED chip and yellow light, which is generated by exciting the fluorescent material with the blue light. Or use a UV LED and fluorescent materials that can emit red, green and blue light. This approach significantly reduces the cost of the white LED lamp and simplifies the drive system. However, this kind of white LED has a low color rendering index (CRI), low efficiency. And the lifetime of the fluorescent material is much shorter compared with a white semiconductor LED.

### SUMMARY OF THE INVENTION

White-light LED lamps are commercially available, but they are not competitive with standard white-light sources in either performance or cost. Accordingly, it is desirable to provide an LED system. In order to reduce the cost and improve the lifetime. It is a general object of the present invention to provide high quantum efficiency white color LED costly.

The white tunnel regenerated light emitting diode (shown as FIGS. 1 and 2) of the invention comprises p type electrode 1, red light cell, tunnel junction 9, green light cell and blue light cell, which connected with each other by tunnel junction 9 or by wafer bonding layer 8, the down chip 17 which are made of blue, green cell and tunnel junction or cyan cell and tunnel junction, n type electrode 13. When forward bias between electrode I and electrode 13, each cell emits relative light and then they mix to emit white light.

The red light cell 14 in the invention comprise p type cap layer 2, DBR layer 3a, up confinement layer 4a, red active layer 5 and down confinement layer 6a and buffer layer 7a.

The green light cell 15 in the invention comprise p type cap layer 2, DBR layer 3b, up confinement layer 4b, green active layer 10, down confinement layer 6b and buffer layer 7b.

The blue light cell 16 in the invention comprise p type cap layer 2, DBR layer 3c, up confinement layer 4c, blue active layer 11, down confinement layer 6c, buffer layer 7c and substrate 12.

The cyan light cell 19 of the invention comprise p type cap layer 2, DBR layer 3d, up confinement layer 4d, cyan active layer 18, down confinement layer 6d, buffer layer 7d and substrate 12.

There is or is not a DBR layer 3a in the red light cell 14.

Each active layer in the invention can be PN junction, or PIN junction, or double hetero-junction, or single quantum well, or multi-quantum wells, or tunnel regenerated multi-active layers, or quantum dot.

Tunnel junction in the invention can be homo junction or hetero junction.

The substrate in the invention can be sapphire, SiC, ZnO or any other materials which transparent to white light and match with the epitaxy growth.

Compared with the traditional pixel white LED, the tunnel regenerated white LED are more simple. The red light cell is much more simple than the common red LED (shown as FIG. 3). Due to without the expensive thickness current spreading layer GaP 20, or maybe without the complex DBR layer 3, epitaxy growth of red light cell is much inexpensive, the total performance are improved.

Compared with the common blue or cyan LED FIG. 4, The blue light cell 16 and cyan light cell 19 have not the current spreading layer 20 and cap layer 22; and the green light cell 15 has not the current spreading layer 20 and substrate 12. The tunnel regenerated white LED of the invention is made of two or three light cells, which are vertically stacked, by tunnel junction or/and wafer bonding technology, it's a integrated LED, but the driving circuit is simple as the single LED.

Compared with the white LED based on a GaN LED and a phosphor layer, the tunnel regenerated white LED of the invention is high efficiency due to only one time opto-electrical conversion, long lifetime and high reliability due to the total semiconductor materials.

The high performance of the high-efficiency tunnel regenerated white LED is described as below:
1. This invention fabricates a white LED by epitaxy growth and wafer bonding technology to stack several relatively independent light cells, and import a p++n++ tunnel junction between each light cell. When reverse bias to the tunnel junction, the electron at the valence band of p type side can tunnel through to the conduction band of n type, and thus become electron in conduction band, the carrier is regenerated, which we called tunnel regenerated. So the carriers injected into red cell and emit red photons, and then the same carriers tunnel through into the green cell, and emit green photons, and then tunnel through into the blue cell, emit blue photons, hence the injected carriers regenerated by tunnel junctions, one carrier can emit different number of photons according to the number of light cells. The light cells of the invention emits three primary colors simultaneously to produce white light, or and mixing of two or three or more colors to produce white light.

2. The tunnel junction improves the current spreading of LED, so the more the tunnel junction, the better the current spreading. There needn't the thickness current spreading layer due to the thin tunnel junction.

3. The each light cell of the invention can be multiple active-layer which emit the same wavelength of light, so the luminance of each light cell can be increased importantly, thus the efficiency and luminance of the tunnel regenerated white LED can be increased heavily, the cost can be decreased.

4. The p type electrode will be the back reflector of the invention, which leads to simple fabrication process, low cost and high productivity efficiency.

5. Vertical stack of different color light cell makes the light mixed at the same light emitting direction, easy to get the optimized color rendering white color.

### BRIEF DESCRIPTION OF THE DRAWINGS

FIG. 1 is a simplified schematic of the tunnel regenerated white light LED include red, green and blue light cell. 1-p type electrode, 2-p type cap layer, 3-DBR layer, 4-up confinement layer, 5-red light active layer, 6a-down confinement layer, 7-buffer layer, 8-wafer bonding layer, 9-tunnle junction, 10-green light active layer, 11-blue light active layer, 12-substrate, 13-n type electrode, 14-red light cell, 15-green light cell, 16-blue light cell, 17-bottom chip, a-for red light, b-for green light materials, c-for blue light. Example: 3a-DBR layers for red light.

FIG. 2 is a simplified schematic of the tunnel regenerated white light LED include red and cyan light cell. 1-p type electrode, 2-p type cap layer, 3-DBR layer, 4-up confinement layer, 5-red light active layer, 6-down confinement layer, 7-buffer layer, 8-wafer bonding layer, 9-tunnle junction, 13-n type electrode, 14-red light cell, 17-bottom chip, 18-cyan active layer, 19 cyan light cell, a-for red light, d-for cyan light. Example: 3a-DBR layers for red light.

FIG. 3 is a simplified schematic of the common red LED. 1-p type electrode, 2-p type cap layer, 3-DBR layer, 4-up confinement layer, 5-red light active layer, 6-down confinement layer, 7-buffer layer, 13-n type electrode, 20-current spreading layer, 21-GaAs substrate, a-for red light. Example: 3a-DBR layers for red light.

FIG. 4 is a simplified schematic of the common blue or green LED. 1-p type electrode, 4-up confinement layer, 6-down confinement layer, 7-buffer layer, 11-blue active layer, 12-substrate, 13-n type electrode, 20-current spreading layer, 22 cap layer, c-for blue light. Example: 4c-up confinement layer for blue light.

FIG. 5 is a simplified schematic of the common pixel white LED. 23-red LED chip, 24-green LED chip, 25-blue LED chip.

FIG. 6 is a simplified schematic of the common white LED based on a blue LED and a phosphor layer. (a) Lamp structure; (b) chip structure. 26-phosphor material, 27-bond wire, 28-blue LED chips, 29-yellow light.

FIG. 7 is an example of the tunnel regenerated white light LED.

FIG. 8 is another example of the tunnel regenerated white light LED in the invention.

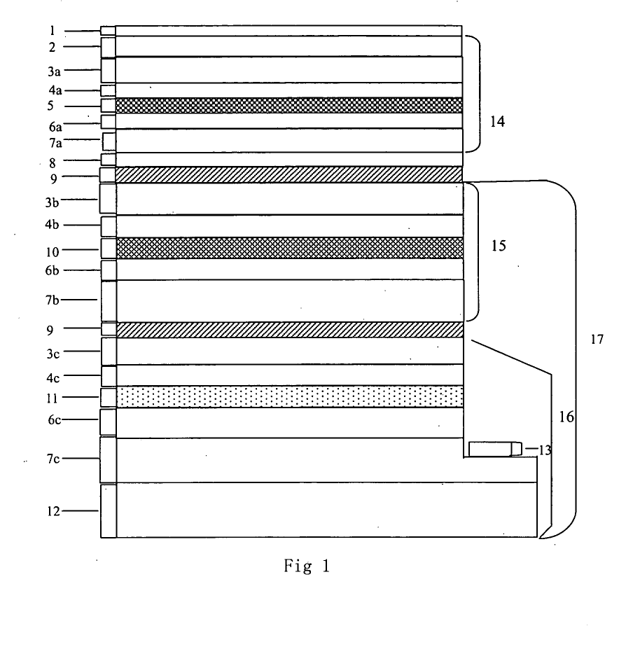

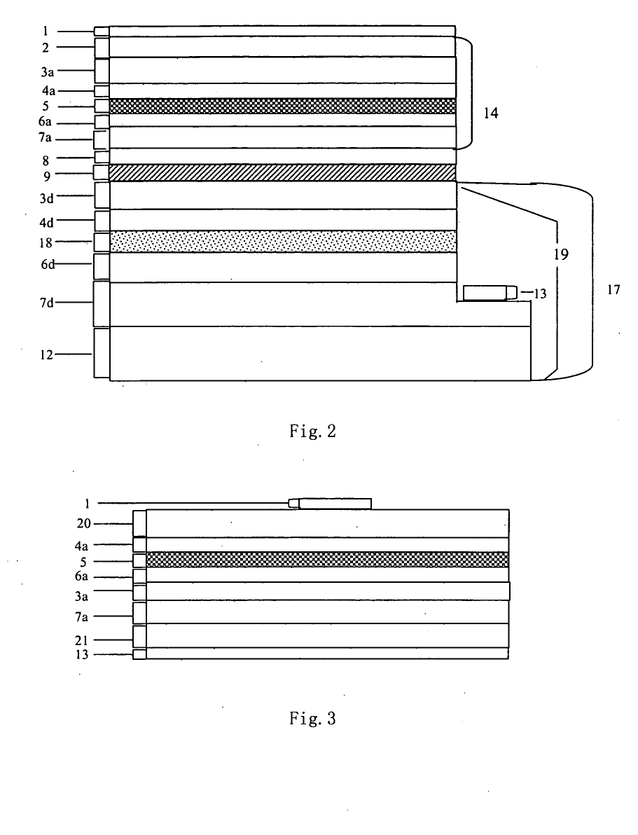

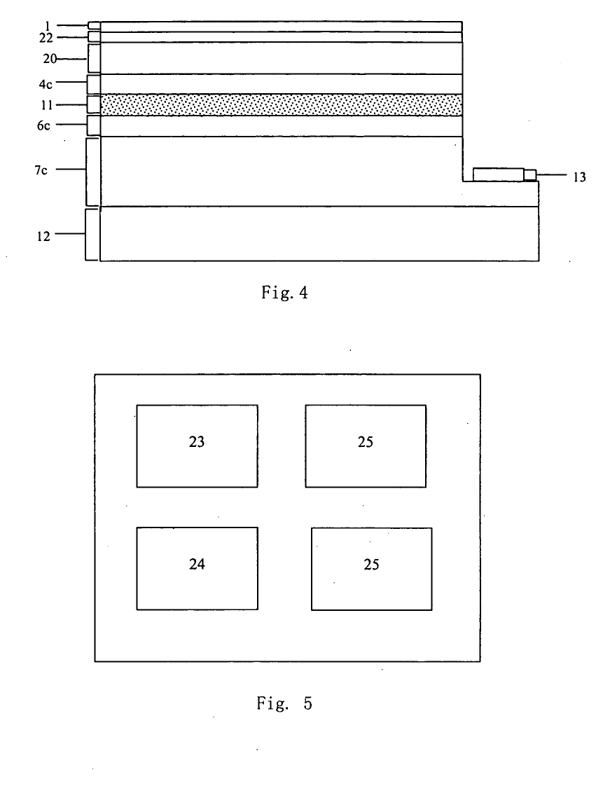

### DETAILED DESCRIPTION OF THE INVENTION

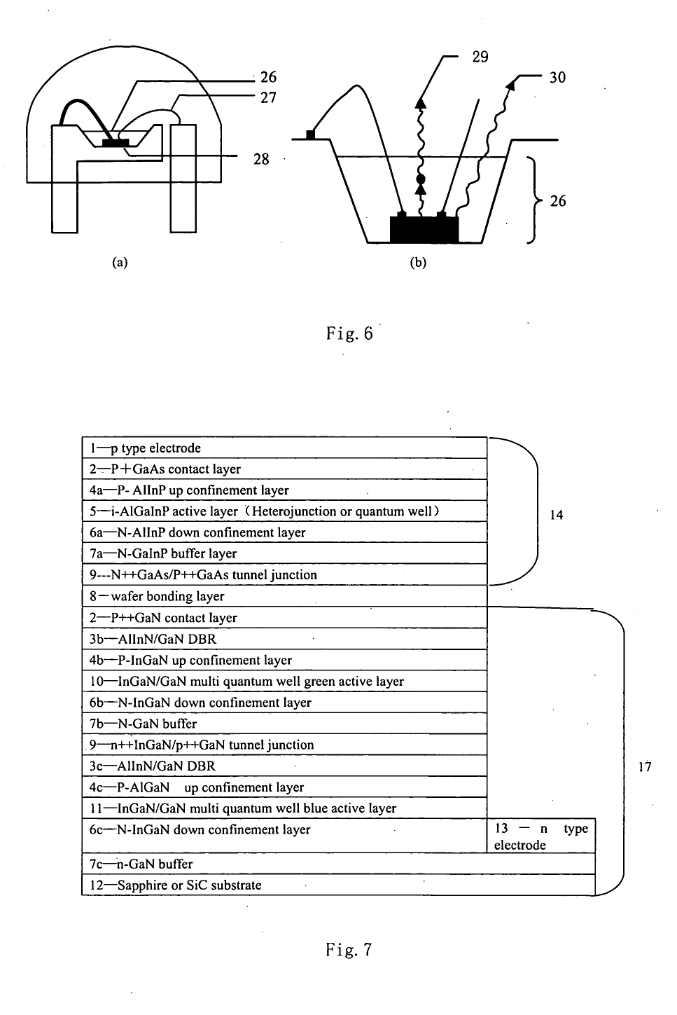

As an example of the tunnel regenerated white LED is schematically shown as FIG. 7, the fabrication process as following:
1. The red light cell was grown in metal-organic chemical vapor deposition (MOCVD) layer by layer: after growing a buffer layer of n+GaAs, then N++/P++ GaAs tunnel junction 9, N-GalnP buffer layer 7a, N-AllnP down confinement layer 6a, AlGaInP/GaInP hetero junction active layer 5, p-AllnP up confinement layer 4a, P++ GaAs cap layer 2. And then thermal deposit or sputter p type metal electrode Ti/Au 1 on the top of p cap layer. And then grinding or liftoff the GaAs substrate and get the red light cell.

2. The green and blue light cell are grown in metal-organic chemical vapor deposition (MOCVD) layer by layer: After growing a n type buffer 7c on the top of sapphire or SiC substrate, n type InGaN down confinement layer 6c, InGaN/GaN multi-quantum wells blue active layer 11, p-AlGaN up confinement layer 4c, AlInN/GaN DBR blue light reflector layer 3c, n++ InGaN/P++GaN tunnel junction 9, n-GaN buffer layer 7b, n-InGaN down confinement layer 6b, InGaN/GaN multi-quantum wells green active layer 10, p-AlGaN up confinement layer 4b, AlInN/GaN DBR green light reflector layer 3b, P++ GaN cap layer 2. After lithography and ICP etching and then e-beam deposit n type electrode, which makes the bottom chip 17.

3. Finally, the tunnel regenerated white LED was fabricated by connect red light cell 14 with bottom chip 17 through wafer bonding technology. Bias between n type electrode 1 and p type electrode 13, the device emits white light.

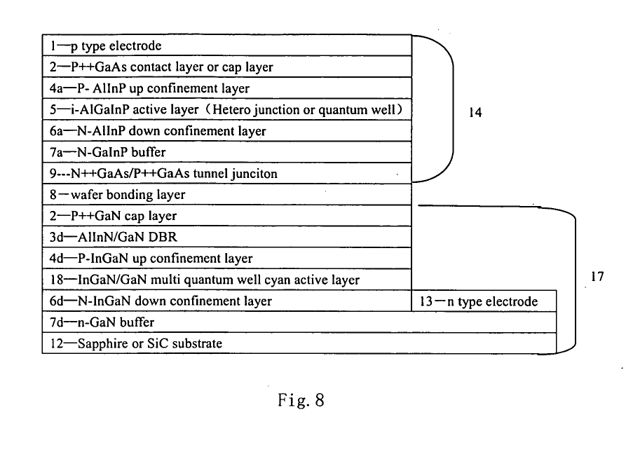

As an example of the tunnel regenerated white LED is schematically shown as FIG. 8, the fabrication process as following:
1. The red light cell was grown in metal-organic chemical vapor deposition (MOCVD) layer by layer: after growing a buffer layer of n+GaAs, then N++/P++ GaAs tunnel junction 9, N-GalnP buffer layer 7a, N-AllnP down confinement layer 6a, AlGaInP/GaInP hetero junction active layer 5, p-AllnP up confinement layer 4a, P++ GaAs cap layer 2. And then thermal deposit or sputter p type metal electrode Ti/Au 1 on the top of p cap layer. And then grinding or liftoff the GaAs substrate and get the red light cell.

2. The cyan light cell are grown in metal-organic chemical vapor deposition (MOCVD) layer by layer: After growing a n type buffer 7d on the top of sapphire or SiC substrate, n type InGaN down confinement layer 6d, InGaN/GaN multi-quantum wells cyan active layer 18, p-AlGaN up confinement layer 4d, AlInN/GaN DBR blue light reflector layer 3d, P++ GaN cap layer 2. After lithography and ICP etching and then e-beam deposit n type electrode, which makes the bottom chip 17.

3. Finally, the tunnel regenerated white LED was fabricated by connect red light cell 14 with bottom chip 17 through wafer bonding technology. Bias between n type electrode 1 and p type electrode 13, the device emits white light.

The invention, in adding multiple active layers through tunnel junction to arrive at an low cost, high efficiency, high luminance white LED.

While the invention has been described with respect to specific embodiments by way of illustration, many modifications and changes will occur to those skilled in the art. It is, therefore, to be understood that the appended claims are intended to cover all such modifications and changes as fall within the true scope and spirit of the invention.

1. A tunneling regenerated white color light-emitting diode comprising: a p type electrode 1, a red light cell, tunnel junction 9, a green light cell and a blue light cell (or a cyan cell), and tunnel junction 9 between green and blue light cells, n type electrode 13, Wherein each cells electrically connected by tunnel junction or both by tunnel junction and wafer bonding layer 8.

2. The tunneling regenerated white LED as claimed in claim 1 wherein said red cell 14 comprises one or multiple red emission regions, wherein each red emission region comprises p type contact layer 2, DBR layer 3a, p type current confinement layer 4a, red light active layer 5, n type confinement layer 6a, buffer layer 7a.

3. The tunneling regenerated white LED as claimed in claim 1 wherein said green cell 15 comprises one or multiple green emission regions, wherein each green emission region comprises p type contact layer, with or without DBR reflect layer 3b, p type current confinement layer 4b, p type barrier layer, green light active layer 10, n type barrier layer and confinement layer 6b, buffer layer 7b.

4. The tunneling regenerated white LED as claimed in claim 1 wherein said blue cell 16 comprises one or multiple blue, wherein each blue or cyan emission region comprises p type contact layer, with or without DBR reflect layer 3c, p type current confinement layer and p type barrier layer 4c, blue light active layer 11, n type barrier layer and confinement layer 6c, buffer layer 7c and transparent substrate 12.

5. The tunneling regenerated white LED as claimed in claim wherein said cyan cell 19 comprises one or multiple cyan light active region, wherein cyan emission region comprises p type contact layer, with or without DBR reflect layer 3d, p type current confinement layer and barrier layer 4d, cyan light active layer 18, n type barrier layer and confinement layer 6d, buffer layer 7d and transparent substrate 12.

6. The tunneling regenerated white LED as claimed in claim 2 wherein said red light cell 14 could be with or without DBR reflect layer 3.

7. The tunneling regenerated white LED as claimed in claim 1 to 6 wherein said each light cell can be PN junction, or PIN junction, or Double hetero Junction, or single quantum well, or multi-quantum wells, or multi-active layers, or quantum dot.

8. The tunneling regenerated white LED as claimed in claim 1 to 6 wherein said the tunnel junction is homo junction, or hetero junction.

9. The tunneling regenerated white LED as claimed in claim 2, wherein said red light cell, the materials diode is a two-terminal structure and red cell on the top, green cell on the middle and blue cell on the bottom; the light from each cell emits out through the transparent substrate at the bottom cell and synthesize white color light.
